(19) United States
(12) Patent Application Publication
(10) Pub. No.: US 2026/0065804 A1
(43) Pub. Date: Mar. 5, 2026

(54) METALLIZED BREATHABLE COMPOSITE FABRIC

(71) Applicant: YiLab Temperature Control Technologies (Changzhou) Co., Ltd., Shanghai (CN)

(72) Inventors: Cindy Yee Cin Lau, Palo Alto, CA (US); Pei Zhu, Santa Clara, CA (US)

(21) Appl. No.: 19/386,203

(22) Filed: Nov. 11, 2025

Related U.S. Application Data
(63) Continuation of application No. 17/827,591, filed on May 27, 2022, now Pat. No. 12,469,406.
Application No. 17/827,591 is a continuation of application No. PCT/US2020/061762, filed on Nov. 23, 2020.
(60) Provisional application No. 62/941,555, filed on Nov. 27, 2019.

(51) Int. Cl. G09B 19/06; B32B 5/02; B32B 7/12; B32B 15/08; B32B 27/06; B32B 27/12; B32B 27/18; B32B 27/40; G06F 3/0482; G06T 7/11; G09B 19/08

(52) U.S. Cl. CPC G09B 19/06; B32B 5/02; B32B 7/12; B32B 15/08; B32B 27/06; B32B 27/12; B32B 27/18; B32B 27/40; G06F 3/0482; G06T 7/11; B32B 2264/105; B32B 2264/30; B32B 2305/18; B32B 2307/724; B32B 2437/00; G06T 2200/24; G09B 19/08

(57) ABSTRACT

A fabric includes an inner layer, a metallized membrane disposed on the inner layer, and an outer layer disposed on the metallized membrane. The metallized membrane includes a base layer containing a polymer and a metal layer deposited on a first surface of the base layer. The inner layer is coupled to the metallized membrane via first point contacts, and the outer layer is coupled to the metallized membrane via second point contacts.

### CROSS-REFERENCE TO RELATED APPLICATION

This application is continuation-in-part application of U.S. patent application Ser. No. 17/827,591, filed May 27, 2022, which is a continuation of International Application No. PCT/US2020/061762, filed Nov. 23, 2020, which claims the benefit under 35 U.S.C. 119(e) of U.S. Provisional Application No. 62/941,555, filed Nov. 27, 2019, the content of each of which is hereby incorporated in its entirety.

### TECHNICAL FIELD

This disclosure is generally related to fabric for apparels, footwears, tents, and sleeping bags, and more specifically to metallized breathable composite fabrics for apparels, footwears, tents, and sleeping bags.

### BACKGROUND

Moisture vapor- and air-permeable metallized polyethylene plexifilamentary film-fibril sheets have been used as house wraps to increase insulation of buildings. However, those sheets are not suitable for garment due to poor hand feel, poor resistance to creases, and poor durability for washing.

### SUMMARY

Described herein are breathable composite fabrics for use in apparels, footwears, tents, and sleeping bags that are comfortable to human use and durable to wash cycles.

In one aspect, a laminated fabric includes an inner layer, a metallized membrane disposed on the inner layer, and an outer layer disposed on the metallized membrane. The metallized membrane includes a base layer containing a polymer and a metal layer deposited on a first surface of the base layer. The inner layer is coupled to the metallized membrane via first point contacts, and the outer layer is coupled to the metallized membrane via second point contacts.

In some embodiments, a fabric includes an inner layer; a metallized membrane disposed on the inner layer, the metallized membrane including a base layer containing a polyethylene and a metal layer deposited on a first surface of the base layer, wherein the inner layer is coupled to the metallized membrane via first point contacts, wherein a first density of the first point contacts is variable across different portions of the inner layer, wherein, an area covered by the first point contacts is below 20 percent of a surface of the outer layer; and an outer layer disposed on the metallized membrane, wherein the outer layer is coupled to the metallized membrane via second point contacts, wherein a second density of the second point contacts is variable across different portions of the outer layer, wherein, an area covered by the second point contacts is below 20 percent of a surface of the outer layer.

In some embodiments, the inner layer is coupled to a second surface of the base layer. The second surface is opposite to the first surface of the base layer. In some embodiments, the outer layer is coupled to a surface of the metal layer.

In some embodiments, each of the inner layer, the base layer, the metal layer, and the outer layer has a moisture vapor transmission rate (MVTR) of at least 500 g/m²/24 hr. In some embodiments, the inner layer has a thermal conductivity at most 0.6 W/m-K. In some embodiments, different regions of the inner layer have different thermal conductivities. For example, because certain areas (e.g., neck, back of torso, abdomen) of a person's body may be more sensitive to heat or temperature changes, the inner layer may be designed to have higher or lower thermal conductivities corresponding to those areas of a person's body. Whether the inner layer has higher or lower thermal conductivities at inner layer regions corresponding to the neck, back of torso, or abdomen may depend on whether the fabric is designed to preserve heat or to provide cooling. If the fabric is designed to provide cooling, then the inner layer may have higher thermal conductivities in inner layer regions corresponding to the neck, back of torso, or abdomen. If the fabric is designed to preserve heat, then the inner layer may have lower thermal conductivities in inner layer regions corresponding to the neck, back of torso, or abdomen. The inner layer may include one of a woven fabric, a knit fabric, or a non-woven fabric. The inner layer may include a synthetic material or a natural material. In some embodiments, the synthetic material is selected from one or more of polyester, nylon, elastane, polyurethane, polyethylene, polypropylene, polylactic acid, or polytetrafluoroethylene (PTFE).

In some embodiments, the fabric has a moisture vapor transmission rate at least 70% of each of the inner layer, the metallized membrane, and the outer layer. In some embodiments, the first and second point contacts are configured in a dot matrix. In some embodiments, the first and second point contacts include an adhesive. In some embodiments, the first point contacts include melted base layer or melted inner layer. In some embodiments, the second point contacts include melted base layer or melted outer layer. In some embodiments, the first point contacts or the second point contacts are formed by sewing or quilting.

In some embodiments, the metal layer includes one or more of aluminum, titanium, silver, gold, copper, zinc, magnesium, germanium, etc. In some embodiments, the metal layer has a thickness of about 10 nanometers to about 200 nanometers. In some embodiments, the metal layer is formed by vapor deposition of a metal onto the first surface of the base layer. In some embodiments, the metal layer has a reflectivity in a range between 0.76 and 0.97 at a wavelength of 9.5 micrometers.

In some embodiments, the base layer has a thickness less than about 50 micrometers or less than about 25 micrometers.

In some embodiments, the first surface of the base layer has a specular gloss of at least 28 percent. The second surface has a roughness that is at least twice as that of the first surface.

In some embodiments, the metallized membrane has a moisture vapor transmission rate of at least 800 g/m²/24 hr. In some embodiments, a combined emissivity of the metallized membrane and the outer layer is at most 0.85 at a wavelength of 9.5 micrometers.

In some embodiments, the apparatus includes the fabric. The apparatus may be one of an apparel, a footwear, a tent, or a sleeping bag.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1A is a schematic diagram depicting a breathable composite fabric, according to one example embodiment.

FIGS. 1B-1D are schematic diagrams depicting a breathable composite fabric, according to example embodiments.

FIG. 2A is a schematic diagram depicting another breathable composite fabric, according to one example embodiment.

FIGS. 2B and 2C are schematic diagrams illustrating an inner layer of a breathable composite fabric, according to one example embodiment.

FIG. 3 is a diagram illustrating thermal resistance retention and emissivity of fabric samples, according to example embodiments.

FIG. 4A-4C are schematic diagrams depicting laminates, according to example embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

Various embodiments described herein are directed to breathable composite fabrics for use in apparels and footwears. In one embodiment, a breathable composite fabric includes an inner layer, a metallized membrane disposed on the inner layer, and an outer layer disposed on the metallized membrane. The metallized membrane includes a base layer containing a polymer and a metal layer deposited on a first surface of the base layer. The inner layer is coupled to the metallized membrane via first point contacts, and the outer layer is coupled to the metallized membrane via second point contacts. The metal layer has a thickness of about 10 nanometers to about 200 nanometers.

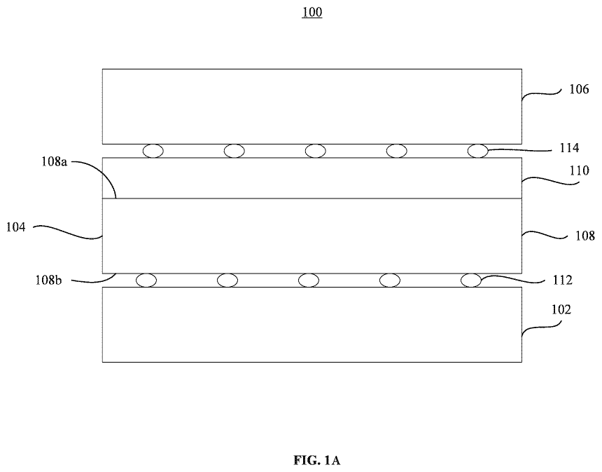

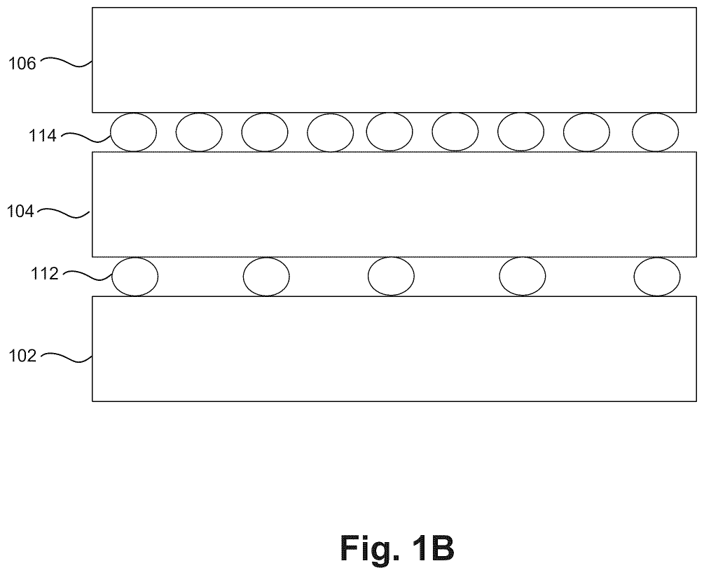

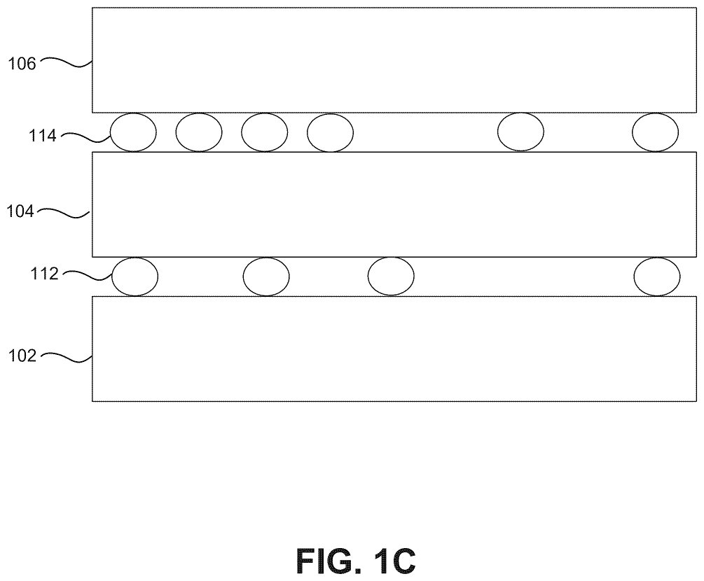

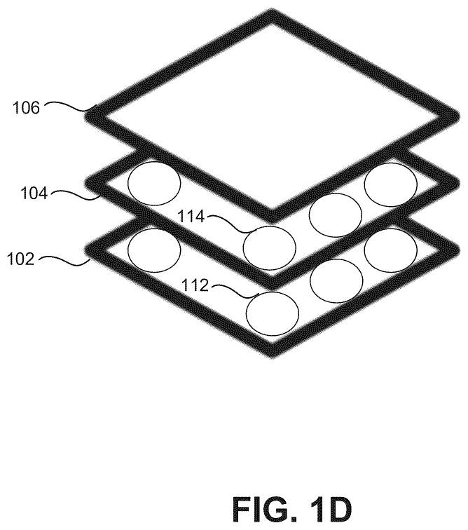

Embodiments will now be explained with accompanying figures. Reference is first made to FIG. 1A. FIG. 1A is a schematic diagram depicting a breathable composite fabric 100 according to one example embodiment. The fabric 100 includes an inner layer 102, a metallized membrane 104 disposed on the inner layer 102, and an outer layer 106 disposed on the metallized membrane 104. The metallized membrane 104 includes a base layer 108 and a metal layer 110 deposited on a first surface 108a of the base layer 108. For example, the metal layer 110 may be formed by vapor deposition of a metal onto the first surface 108a of the base layer 108. The inner layer 102 and the metallized membrane 104 are coupled to each other via first point contacts 112. The first point contacts 112 may be arranged in a dot matrix. The first point contacts 112 connect the inner layer 102 to a second surface 108b of the base layer 108. The outer layer 106 and the metallized membrane 104 are coupled to each other via second point contacts 114. The second point contacts 114 may be arranged in a dot matrix. The second point contacts 114 connect the outer layer 106 to a surface of the metal layer 110. In the configuration illustrated in FIG. 1A, the base layer 108 is sandwiched between the inner layer 102 and the metal layer 110.

FIGS. 1B-1D illustrate different distributions or densities (e.g., concentrations) of the first point contacts 112 and the second point contacts 114. For example, in FIG. 1, a first density of the first point contacts 112 is different from a second density of the second point contacts 114. This may balance between different, potentially conflicting considerations, such as breathability and durability. For example, the first density of the first point contacts 112 may be less than the second density of the second point contacts 114 to promote breathability near the inner layer 102, while maintaining durability at the outer layer 106. Other embodiments are also possible, such as the first density of the first point contacts 112 being greater than the second density of the second point contacts 114.

In FIG. 1C, the first density of the first point contacts 112 and the second density of the second point contacts 114 may be variable across a planar region separating the inner layer 102 from the metallized membrane 104, and/or across a planar region separating the metallized membrane 104 from the outer layer 106. This may be because different regions of the breathable composite fabric 100 may experience different magnitudes and/or directions of applied force. Thus, a higher density of the first point contacts 112 and/or the second point contacts 114 may correspond to regions that experience a greater magnitude of force.

In FIG. 1D, the first density of the first point contacts 112 and/or the second density of the second point contacts 114 may be variable across, along, or with respect to different directions or axes. For example, in FIG. 1D, the first density or the second density may be higher or lower along a vertical direction, compared to a horizontal direction. For example, the vertical direction may correspond to a height direction of a person when the person is wearing the fabric 200. Going along the vertical direction may encompass changing a height (e.g., from a person's waist to a person's neck). The horizontal direction may correspond to positions along a same height (e.g., along a front portion of a person's skin). A depth direction may correspond to positions along a same height but going from a front to a back surface of the fabric 200 or one or more layers thereof. The first density or the second density may be higher or lower because forces applied in one direction may be higher than forces applied in another direction. For example, a fabric may be stretched more often along a vertical direction rather than a horizontal direction so the first density or the second density may be higher along a vertical direction so that the first density or the second density is higher along a vertical direction as opposed to a horizontal direction. Overall, FIGS. 1B-1D illustrate configurations of first and second point contacts between the inner layer 102, the outer layer 106, and the metallized membrane 104, which address breathability and durability.

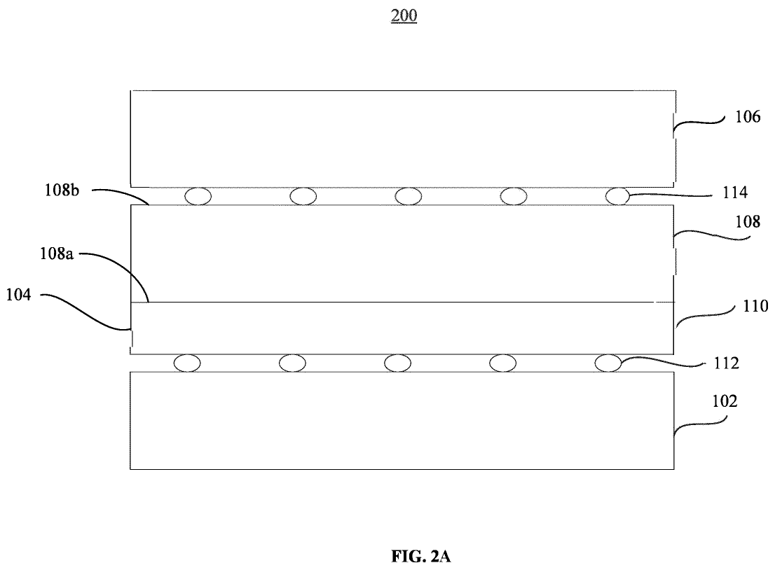

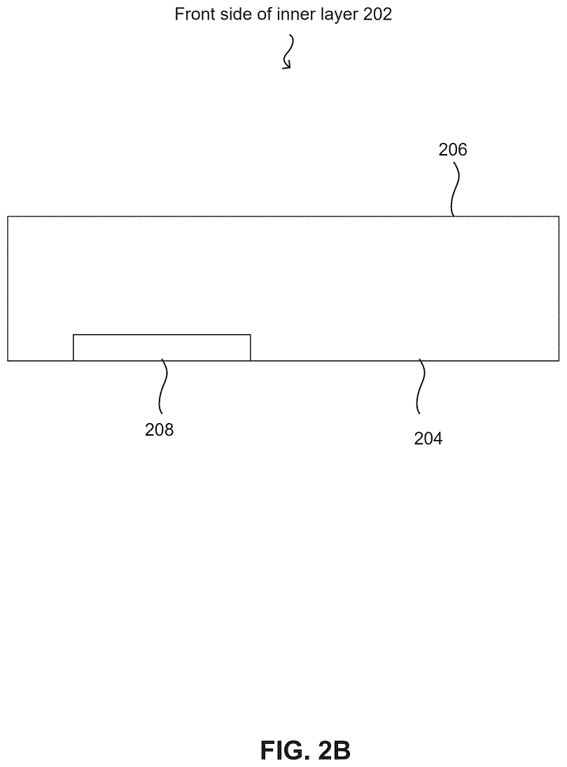

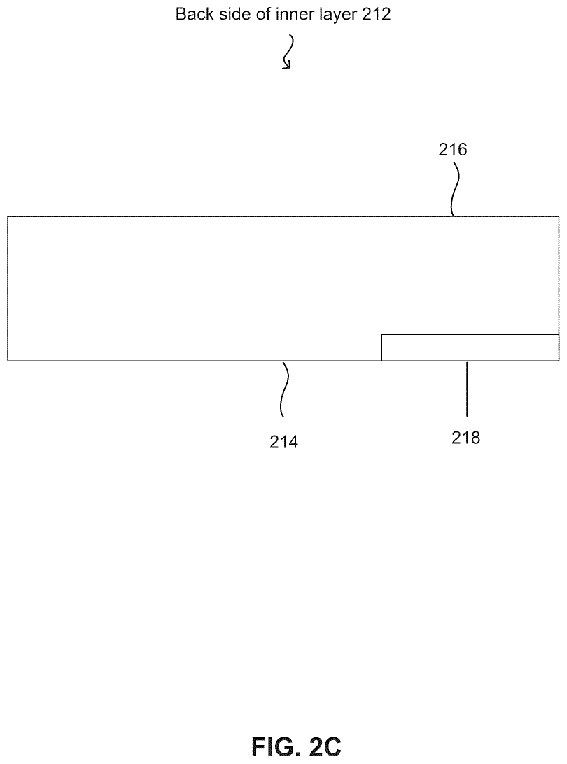

FIG. 2A is a schematic diagram depicting another breathable composite fabric 200 according to one example embodiment. The fabric 200 is similar to the fabric 100 with a modification where the metal layer 110 is sandwiched between the inner layer 102 and the base layer 108. In fabric 200, the first point contacts 112 connects the inner layer 102 to a surface of the metal layer 110. The second point contacts 114 connects the outer layer 106 to the second surface 108b of the base layer 108. The structure of the fabric 200 can better protect the metal layer 110 from scratches or other accidental damages during the subsequent processing and use.

The inner layer 102 is configured to add high breathability to the breathable composite fabrics 100 and 200 to make apparels and footwears that are more comfortable to wear. The inner layer 102 is also configured to be sufficiently strong, when combined with appropriate outer layer 106, to resist repeated dynamic/mechanical actions, such as wash cycles.

In some embodiments, the inner layer 102 has a moisture vapor transmission rate of at least 500 g/m²/24 hr. In some embodiments, to provide further breathability the inner layer 102 has a moisture vapor transmission rate of at least 750 g/m²/24 hr, at least 1000 g/m²/24 hr, or at least 1500 g/m²/24 hr. Including the inner layer 102 in the breathable composite fabrics 100 and 200 also provides soft touch feeling to human body, good hand feel and drape for next-to-skin application. In some embodiments, the inner layer 102 has a thickness of at least 60 micrometers to endure the wear and tear during its useful life time. Depending on where the breathable composite fabric 100 or 200 is applied to, the thickness of the inner layer 102 may vary. For example, the thickness of the inner layer 102 may be from about 60 micrometers to about 2400 micrometers, from about 60 micrometers to about 1500 micrometers, from about 60 micrometers to about 1000 micrometers, from about 60 micrometers to about 750 micrometers, or from about 60 micrometers to about 500 micrometers.

In some embodiments, the inner layer 102 includes one or more of a woven fabric, a knit fabric, or a non-woven fabric. In some embodiments, the inner layer 102 includes a synthetic material or a natural material. For example, the synthetic material for the inner layer 102 is selected from one or more of polyester, polyamide, polyurethane, polyolefin, polylactic acid, nylon, elastane, and PTFE. Further, the natural material for the inner layer 102 may include cotton, wool, silk, linen, and other natural fibers.

In some embodiments, the fabric 100 or 200 may have low thermal conductivity, typically not more than 0.1 W/m-K or at most 0.6 W/m-K, to minimize conductive heat loss.

In some embodiments, the inner layer 102 has a tensile strength at least 45 N/2.54 cm under ASTM (American Society of Testing Materials) D5035 test conditions, a tear strength at least 9N under ASTM 2261 test conditions, and a Mullen burst at least 350 kPa under ASTM D774 test conditions.

In some embodiments, different regions of the inner layer 102 have different properties such as thermal conductivities. For example, because certain areas (e.g., neck, back of torso, abdomen) of a person's body may be more sensitive to heat or temperature changes, the inner layer 102 may be designed to have higher or lower thermal conductivities corresponding to those areas of a person's body. Whether the inner layer 102 has higher or lower thermal conductivities at inner layer regions corresponding to the neck, back of torso, or abdomen may depend on whether the fabric is designed to preserve heat or to provide cooling. If the fabric is designed to provide cooling, then the inner layer 102 may have higher thermal conductivities in inner layer regions corresponding to the neck, back of torso, or abdomen. If the fabric is designed to preserve heat, then the inner layer 102 may have lower thermal conductivities in inner layer regions corresponding to the neck, back of torso, or abdomen. The inner layer 102 may include one of a woven fabric, a knit fabric, or a non-woven fabric. The inner layer 102 may include a synthetic material or a natural material. In some embodiments, the synthetic material is selected from one or more of polyester, nylon, elastane, polyurethane, polyethylene, polypropylene, polylactic acid, or polytetrafluoroethylene (PTFE). Although the above description focuses on thermal conductivity, different regions of the inner layer 102 may have different other properties such as different moisture vapor transmission rates or tensile strengths. For example, different regions of the inner layer 102 may have higher or lower moisture vapor transmission rates because certain regions of skin may be more sensitive to breathability such as regions having skin folds (e.g., underarms). As a specific example, an inner layer region corresponding to the underarms or other skin folds may have a higher moisture vapor transmission rate compared to other portions of the inner layer 102.

FIG. 2B illustrates a front side 202 of the inner layer 102. The front side 202 may correspond to a portion of the inner layer 102 that contacts a person's skin on a front side (e.g., including stomach and chest). The front side 202 includes an inner side 204 which faces or directly contacts a person's skin and an outer side 206 that contacts or faces the metallized membrane 104 and is farther from a person's skin compared to the inner side 204. In some embodiments, the front side 202 may contain one or more inner layer regions 208, which have different properties (e.g., thermal conductivity or moisture vapor transmission rate) compared to other portions of the front side 202 or the inner layer 102. The inner layer region 208 may have a higher or lower thermal conductivity compared to other portions of the front side 202. As a specific example, the inner layer region 208 may correspond to a person's stomach area which may be more sensitive to rapid temperature changes, and therefore, the inner layer region 208 may have lower thermal conductivity. Although the inner layer region 208 is illustrated as extending only partially through a thickness of the front side 202, in some embodiments, the inner layer region 208 may extend entirely through a thickness of the front side 202, such as extending from the inner side 204 to the outer side 206. The inner layer region 208 may extend through any portion of the thickness of the front side 202, such as from between 10 percent to 100 percent, 20 percent to 90 percent, 30 percent to 80 percent, 40 percent to 70 percent, 50 percent to 60 percent, or any subrange or value within any range or subrange. Although only a single continuous inner layer region 208 is illustrated for simplicity, it is contemplated that the front side 202 may contain a plurality of discontinuous inner layer regions. In some embodiments, the one or more inner layer regions 208 may cover any percentage of the surface area of the front side 202 (e.g., the inner side 204, the outer side 206, or a combination of the inner side 204 and the outer side 206), such as 10 percent, 15 percent, 20 percent, 25 percent, 30 percent, 35 percent, 40 percent, 45 percent, 50 percent, or any range therebetween such as 10 percent to 50 percent.

In some embodiments, the inner layer region 208 may have properties that are a threshold range relative to one or more other portions of the inner layer 102. For example, the inner layer region 208 may have thermal conductivity of no more than a threshold percentage of the thermal conductivity of one or more other portions of the inner layer 102. The threshold percentage may be any percentage such as 80 percent, 70 percent, 60 percent, 50 percent, 40 percent, 30 percent, 20 percent, 10 percent, any ranges therebetween, or any values therebetween.

FIG. 2C illustrates a back side 212 of the inner layer 102. The back side 212 may correspond to a portion of the inner layer 102 that contacts a person's skin on a back side (e.g., including a person's back). The back side 212 includes an inner side 214 which faces or directly contacts a person's skin and an outer side 216 that contacts or faces the metallized membrane 104 and is farther from a person's skin compared to the inner side 214. In some embodiments, the back side 212 may contain one or more inner layer regions 218, which have different properties (e.g., thermal conductivity or moisture vapor transmission rate) compared to other portions of the back side 212 or the inner layer 102. For example, the inner layer region 218 may have a higher or lower thermal conductivity compared to other portions of the back side 212. As a specific example, the inner layer region 218 may correspond to a person's neck area which may be more sensitive to rapid temperature changes, and therefore, the inner layer region 218 may have lower thermal conductivity. Although the inner layer region 218 is illustrated as extending only partially through a thickness of the back side 212, in some embodiments, the inner layer region 218 may extend entirely through a thickness of the back side 212, such as extending from the inner side 214 to the outer side 216. The inner layer region 218 may extend through any portion of the thickness of the back side 212, such as from between 10 percent to 100 percent, 20 percent to 90 percent, 30 percent to 80 percent, 40 percent to 70 percent, 50 percent to 60 percent, or any subrange or value within any range or subrange. Although only a single continuous inner layer region 218 is illustrated for simplicity, it is contemplated that the back side 212 may contain a plurality of discontinuous inner layer regions. In some embodiments, the one or more inner layer regions 218 may cover any percentage of the surface area of the back side 212 (e.g., the inner side 214, the outer side 216, or a combination of the inner side 214 and the outer side 216), such as 10 percent, 15 percent, 20 percent, 25 percent, 30 percent, 35 percent, 40 percent, 45 percent, 50 percent, or any range therebetween such as 10 percent to 50 percent.

In some embodiments, the inner layer region 218 may have properties that are a threshold range relative to one or more other portions of the inner layer 102. For example, the inner layer region 218 may have thermal conductivity of no more than a threshold percentage of the thermal conductivity of one or more other portions of the inner layer 102. The threshold percentage may be any percentage such as 80 percent, 70 percent, 60 percent, 50 percent, 40 percent, 30 percent, 20 percent, 10 percent, any ranges therebetween, or any values therebetween.

Having inner layer regions 208, 218 on the front or back sides 202, 212 constitutes a technical benefit of adapting to a person's different skin sensitivities depending on a relative location of a portion of the person's skin. This improves not only comfort but also health because a person is less likely to become sick due to excessive heat, cold, or moisture on portions of skin that are especially sensitive to such changes in environmental conditions. The inner layer regions 208, 218 may be fabricated using different materials that have different properties (e.g., moisture vapor transmission rate or thermal conductivity) or different thicknesses.

The above principles as described with respect to the inner layer 102, that different portions of the inner layer 102 may have different or non-uniform properties, may be extended and applicable to other layers, such as the metallized membrane 104, the base layer 108, the metal layer 110, or the outer layer 106.

The metallized membrane 104 is provided as a breathable radiant barrier for insulation purposes. For those purposes, the metallized membrane 104 is configured to have low emissivity and high breathability. In some cases, the metallized membrane 104 is water proof. For example, the degree of waterproofness or water resistance (e.g., an amount of water pressure that the metallized membrane 104 can withstand before leaking) has been measured to be between 616 mm H₂O and 750 mm H₂O, with an average of 696 mm H₂O during one experimental trial. The experimental trial was conducted consistent with American Association of Textile Chemists and Colorists Test Method (AATCC TM) 127-2018 protocol. During the experimental trial, one surface of the metallized membrane 104 is subjected to a hydrostatic pressure, which increases at a constant rate, until leakage (e.g., three points of leakage) appear on an opposing surface. During the experimental trial, the rate of increase of water pressure was approximately 60 millibarometers (mbar) per minute. A temperature of the distilled water was approximately 21 degrees Celsius. The water enters the metallized membrane from the silver (e.g., metallized) side. A face side of the metallized membrane 104 faced the water during the trials. During other trials, the degree of water resistance was measured to be higher, for example, between 1000 mm H₂O and 5000 mm H₂O using the same testing protocol. The metallized membrane 104 may be configured to be a breathable IR reflective layer to enhance thermal insulation through radiation reflection.

In some embodiments, the metallized membrane 104 has a moisture vapor transmission rate of at least 500 g/m²/24 hr. In some embodiments, to provide further breathability, the metallized membrane 104 may have a moisture vapor transmission rate of at least 800 g/m²/24 hr, at least 1000 g/m²/24 hr, at least 1500 g/m²/24 hr, at least 2000 g/m²/24 hr, or at least 2500 g/m²/24 hr. In some embodiments, the metallized membrane 104 has nonuniform properties, similar to that described with respect to the inner layer 102, for example, in FIGS. 2B and 2C.

In some embodiments, the base layer 108 of the metallized membrane 104 includes a polymer. To be effective for its purposes, the base layer 108 has a thickness less than about 50 micrometers, or less than 25 micrometers, or less than about 20 micrometers, or less than about 15 micrometers, or less than about 10 micrometers. In some embodiments, the base layer 108 has an infrared transparency of at least about 40% at a wavelength of 9.5 micrometers. In some embodiments, the base layer 108 has an infrared transparency of about 40% to 60% at wavelength of 7-14 micrometers.

The first surface 108a of the base layer 108 is configured to be flat, which results in a more effective reflection layer after the base layer 108 is metallized. In some embodiments, the base layer 108 includes polyethylene, which has a lower melting point than many conventional fabric materials so that it can achieve flatter surface through calendaring at a lower temperature. In some embodiments, the base layer 108 may include one or more other materials, such as polyurethane, thermoplastic polyurethane, polyester, polyamide, ePTFE membrane, etc. In some embodiments, the base layer 108 may include an IR transparent substrate, such as polyolefin, which is beneficial because it minimally hinders the reflectivity of the metal layer 110 deposed on either side of the base layer 108. The structure of the base layer 108 is configured to maximize the thermal radiation to be reflected back to the body because minimal heat is consumed to warm up the base layer 108 due to absorption. In some embodiments, the base layer 108 may be porous. In some embodiments, the base layer 108 has nonuniform properties, similar to that described with respect to the inner layer 102, for example, in FIGS. 2B and 2C.

The metal layer 110 may be formed on the base layer 108 by vapor deposition or other plating techniques. For example, metal can be deposited on the microporous base layer 108 through methods like physical vapor deposition (PVD) including sputtering, electron beam deposition, etc. The metal forms a discontinuous layer 110 to maintain breathability/porosity. In some embodiments, the metal layer 110 may include one or more of aluminum, titanium, silver, gold, copper, zinc, magnesium, germanium, etc. In some embodiments, the metal layer 110 may have a thickness of about 10 nanometers to about 200 nanometers, about 10 nanometers to about 100 nanometers, or about 10 nanometers to about 50 nanometers so as to provide pores for breathability. Other metals and thickness are contemplated so that the metal layer 110 has an emissivity of no more than 0.5 for infrared radiation at a wavelength of 9.5 micrometers.

In some embodiments, the metal layer 110 is configured to have a thickness and surface coverage to provide a reflectivity in a range between 0.76 and 0.97 at a wavelength of 9.5 micrometers determined by, for example, Fourier-transform infrared spectroscopy (FTIR). In some embodiments, the metal layer 110 has a reflectivity of 0.8 at a wavelength of 9.5 micrometers. In some embodiments, the metal layer 110 has nonuniform properties, similar to that described with respect to the inner layer 102, for example, in FIGS. 2B and 2C.

In one instance, each of nanoporous polyethylene and polypropylene base layers (about 40% porosity, 16-25 um thick) covered with about 100 nm aluminum can achieve a moisture vapor transmission rate of at least 2500 g/m²/24 hrs. Their reflectivity at a wavelength of 9.5 micrometers is at least 0.97 on the aluminum side and at least 0.87 on the polyolefin side.

The outer layer 106 is configured to be strong, when combined with the appropriate inner layer 102, to resist repeated dynamic/mechanical actions including wet conditions such as machine washing, and dry conditions such as rubbing, crocking, and machine drying.

In some embodiments, the outer layer 106 has, or some regions of the outer layer 106 have, a moisture vapor transmission rate of at least 500 g/m²/24 hr. In some embodiments, to provide further breathability the inner layer 102 has a moisture vapor transmission rate of at least 750 g/m²/24 hr, at least 1000 g/m²/24 hr, or at least 1500 g/m²/24 hr. In some embodiments, the outer layer 206 has nonuniform properties, similar to that described with respect to the inner layer 102, for example, in FIGS. 2B and 2C.

In some embodiments, the outer layer 106 includes one of a woven fabric, a knit fabric, a non-woven fabric, a film or a membrane. In some embodiments, the outer layer 106 includes a synthetic material or a natural material. For example, the synthetic material for outer layer 106 is selected from one or more of polyester, polyamide, polyurethane, polyolefin, polylactic acid, nylon, elastane, and PTFE. Further, the natural material for outer layer 106 may include cotton, wool, silk, linen, and other natural materials.

In some embodiments, the combined emissivity of the metallized membrane 104 and the outer layer 106 may be at most 0.85. This would maintain about 45% of the thermal resistance of the metallized sheet 104 in absence of the outer layer. A suitable emissivity may be obtained by various choice of the outer layer 106. For example, when the outer layer 106 is made with a high IR transmittance material (e.g., polyolefins) and thin (e.g., less than 400 μm), the outer layer 106 may have a high cover factor (e.g., more than 90%). As used herein, a cover factor is defined as the ratio of a surface area covered by solid components such as yarns or fibers to form the outer layer 106, to the total fabric surface area. For a less/non IR-transparent material (e.g., polyester, nylon, elastane, polyurethane, polylactic acid, PTFE, cotton, wool, silk, linen etc.), the outer layer 106 may have a lower cover factor (e.g., about or below 75%) so that a portion of the metallized reflective sheet 104 is exposed. For a less/non IR-transparent material, a surface coverage of more than 90% would result in a combined emissivity being too high (>0.85) hence significantly reducing the thermal resistance achieved by the metallized sheet 104.

Table 1 below summarizes material selections of outer layers in connection with combined emissivity (metallized sheet+outer player). Samples A-D were prepared with the same metallized sheet—an aluminized nanoporous polyolefin film having reflectivity of 0.97 on the aluminum side and 0.87 on the polyolefin side at a wavelength of 9.5 micrometers. Sample A includes an outer layer made of nonwoven polyolefin (IR transparent) having a thickness of 0.16 mm. The outer layer of sample A has a cover factor of 100%. Sample A has an acceptable combined emissivity of 0.47-0.53. Sample B is same as sample A except that sample B includes coating/finishing/printing (less than 6 g/m²) on the surface of the outer layer. Sample B has an acceptable combined emissivity of 0.58-0.78. In Samples A and B, having outer layer material of nonwoven polyolefin provides desirable properties such as being durable, strong (e.g., high tensile strength, tear-resistance, and abrasion resistance), lightweight, water-resistant, chemical or electrolyte resistant (e.g., a bacteria barrier), flame retardant, washable, thermally or acoustically insulating, or breathable. In some embodiments, the nonwoven polyolefin is highly conformable to skin contact surfaces. In some embodiments, the nonwoven polyolefin has hydrophobic properties. For example, a contact angle of a water droplet when the water droplet is placed on a nonwoven polyolefin surface may range from 130 to 140 degrees or any value or subrange thereof. To make the nonwoven polyolefin, resin such as polypropylene resin may be melted and spun into fibers which may be bonded together using heat or pressure, in order to form a sheet or web. In some embodiments, the nonwoven polyolefin is biodegradable. In some embodiments, the nonwoven polyolefin fibers are bonded together with or without additional adhesives.

In some embodiments, the nonwoven polyolefin may include a core and a sheath. In some embodiments, the sheath includes polyethylene such as high density polyethylene, low density polyethylene, or linear low density polyethylene and the core includes polypropylene. Using polyethylene as the sheath material provides benefits of softness, as well as a surface that can be radiation sterilized. The polypropylene core provides benefits of strength and integrity during thermal bonding and provides a three-dimensional network. In some embodiments, the core includes isotactic and syndiotactic polypropylene, such as a melt blend of isotactic and syndiotactic polypropylene. In some embodiments, the nonwoven polyolefin includes nanofibers such as nanosilicon oxide which may confer additional water absorption, flex, stiffness, or rigidity. In some embodiments, the nonwoven polyolefin contains stabilizers (e.g., primary or secondary stabilizers) such as antioxidant stabilizers that prevent thermal oxidation or confer stability against ultra-violet (UV) radiation. Stabilizers may include, as nonlimiting examples, phenols such as hindered phenols, phosphite esters, thioesters, hindered amine stabilizers. In some embodiments, the nonwoven polyolefin may contain nanoparticles which may improve dyeability, heat conductive properties, and other properties. Nanoparticles may contain, for example, calcium oxide, zinc oxide, aluminum oxide, silicon oxide, carbon nanotube clay, other clay, or boehmite. In some embodiments, the nonwoven polyolefin may have more than 50 percent of fibrous mass made up of fibers with a length to diameter ratio greater than 300 or more than 50 percent of fibrous mass with either length to diameter ratio greater than 600 or fabric density less than 0.4 grams per cubic centimeter.

Sample C includes an outer layer made of knit of polyester fully drawn yarn (FDY) (less IR transparent). The outer layer of sample C has a thickness of 0.38 mm and has a cover factor of 67-71%. In some embodiments, the cover factor of 67-71% may be mapped to a specific acceptable range of the combined emissivity, which reduces thermal resistance by the metallized sheet. Sample C also has an acceptable combined emissivity of 0.63. Sample D includes an outer layer made of cotton (IR opaque). The outer layer of sample D has a thickness of 0.38 mm and has a cover factor of 94%. Sample D also has a failed combined emissivity of 0.89 due to the use of an IR opaque material with a high cover factor.

| | Sample A | Sample B | Sample C | Sample D |
|---|---|---|---|---|
| Metallized sheet | Aluminized nanoporous polyolefin. | | | |
| | Reflectivity at 9.5 um = 0.97 | | | |
| | (aluminum side), 0.87 (polyolefin side) | | | |
| Outer layer | Polyolefin | Polyolefin | Polyester | Cotton |
| material | nonwoven | nonwoven + <6 | FDY knit | |
| | | g/m² print | | |
| Outer layer | 0.16 | 0.16 | 0.38 | 0.38 |
| thickness (mm) | | | | |
| Outer layer | 100% | 100% | 67-71% | 94% |
| surface coverage | | | | |
| Combined | 0.47-0.53 | 0.58-0.78 | 0.63 | 0.89 (failed) |
| emissivity | | | | |

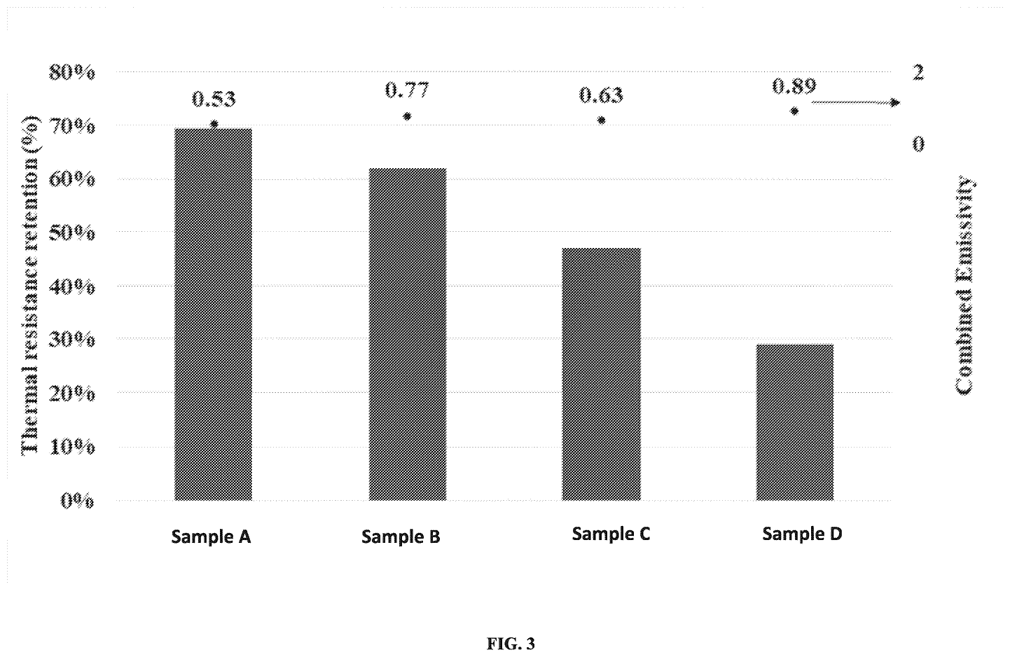

FIG. 3 is a diagram illustrating thermal resistance retention and emissivity of samples A-D as shown in Table 1. As shown in FIG. 3, the thermal resistance retention of samples A-D is 69%, 62%, 47%, and 29%, respectively.

As shown in Table 1, the outer layer is not limited to a single component material and may have thin coating/finishing. For example, sample B includes light prints (e.g., add-on weight of <6 g/m²) on a 0.16 mm polyethylene non-woven film that has a minor effect on the composite's IR reflectivity. In some embodiments, it is found that small loading (<2%) of additives such as color pigment to the IR-transparent material also has an insignificant effect on the composite's IR reflectivity. These fabrics provides more flexibility and color/pattern choices for making apparels, footwears, etc.

The inner layer 102 and the metallized membrane 104 are coupled with each other via a plurality of first point contacts 112. In some embodiments, the metallized membrane 104 can be adhered to the inner fabric through adhesives, such as water-based adhesives, solvent-based adhesives, heat-activated adhesives, or pressure-activated adhesives. The adhesives are disposed on one or both of the inner layer 102 and the metallized membrane 104 to adhere them together. The adhesives are applied in a way that does not significantly reduce the breathability of the breathable composite fabric 100 or 200. For example, this can be achieved through applying the adhesives as the first point contacts 112 in a dot matrix instead of a monolithic film.

In some embodiments, the inner layer 102 and the metallized membrane 104 may be combined through ultrasonic or laser welding. The metallized membrane 104 may also be coupled to the underlying inner layer 102 by heating the point contacts to above the melting point of the base layer 108 or the inner layer 102. For example, a portion of the base layer 108 may be melted to form the first point contacts 112 to connect to the inner layer 102. Or a portion of the inner layer 102 may be melted to form the first point contacts 112 to connect to the base layer 108 (FIG. 1) or the metal layer 110 (FIG. 2A). In some embodiments, both a portion of the inner layer 102 and a portion of the base layer 108 may be melted to form the first point contacts 112 between the inner layer 102 and the metallized membrane 104. In some embodiments, the first point contacts 112 may be formed by sewing or quilting.

The first point contacts 112 are interposed between the inner layer 102 and the metallized membrane 104 in a manner to minimize the impact on breathability of fabric 100 or 200. For example, the first point contacts 112 has an area covering less than 80% of the inner layer 102 (or the metallized membrane 104). For improved breathability, the first point contacts 112 covers less than 50% or 40% or 30% of the inner layer 102 (or the metallized membrane 104). In one embodiment, for even better breathability, the first point contacts 112 covers less than 20% of the inner layer 102 (or the metallized membrane 104).

The first point contacts 112 interposed between the inner layer 102 and the metallized membrane 104 may be arranged in a dot matrix of any form. A density of the first point contacts 112 may be uniform across the entire breathable composite fabric 100 or 200. In some embodiments, the density of the first point contacts 112 may vary from one to another region. For example, the density of the first point contacts 112 may be increased at areas where heavy wear and tear are expected. The density of the first point contacts 112 may be determined in an effort to optimize both breathability and durability considerations. In some embodiments, the density of the first point contacts 112 may be dependent on the density of the second point contacts 114. For example, if the density of the first point contacts 112 is higher, then the density of the second point contacts may be lower. In some embodiments, an average cumulative density of the first point contacts 112 and the second point contacts 114, considered altogether, may be less than 20 percent.

The outer layer 106 and the metallized membrane 104 are coupled with each other via a plurality of second point contacts 114. In some embodiments, the metallized membrane 104 can be adhered to the outer layer 106 through adhesives, such as water-based adhesives, solvent-based adhesives, heat-activated adhesives, or pressure-activated adhesives. The adhesives are disposed on one or both of the outer layer 106 and the metallized membrane 104 to adhere them together. The adhesive is applied in a manner that does not significantly reduce the breathability of the breathable composite fabric 100 or 200. For example, this can be achieved through applying the adhesives as the second point contacts 114 in a dot matrix instead of a monolithic film.

In some embodiments, the outer layer 106 and the metallized membrane 104 may be combined through ultrasonic or laser welding. The metallized membrane 104 may also be coupled to the outer layer 106 by heating the point contacts to above the melting point of the base layer 108 or the outer layer 106. For example, a portion of the base layer 108 may be melted to form the second point contacts 114 to connect to the outer layer 106. Or a portion of the outer layer 106 may be melted to form the second point contacts 114 to connect to the metal layer 110 (FIG. 1A) or the base layer 108 (FIG. 2A). In some embodiments, both a portion of the outer layer 106 and a portion of the base layer 108 may be melted to form the second point contacts 114 between the outer layer 106 and the metallized membrane 104 (FIG. 2A). In some embodiments, the second point contacts 114 may be formed by sewing or quilting.

The second point contacts 114 are interposed between the outer layer 106 and the metallized membrane 104 in a manner to minimize the impact on breathability of fabric 100 or 200. For example, the second point contacts 114 has an area covering less than 80% of the outer layer 106 (or the metallized membrane 104). For improved breathability, the second point contacts 114 covers less than 50% or 40% or 30% of the outer layer 106 (or the metallized membrane 104). In one embodiment, for even better breathability, the second point contacts 114 covers less than 20% of the outer layer 106 (or the metallized membrane 104).

The second point contacts 114 interposed between the outer layer 106 and the metallized membrane 104 may be arranged in a dot matrix of any form. A density of the second point contacts 114 may be uniform across the entire breathable composite fabric 100 or 200. In some embodiments, the density of the second point contacts 114 may vary from one to another region. For example, the density of the second point contacts 114 may be increased at areas where heavy wear and tear are expected.

In some embodiments, the breathable composite fabric 100 or 200 has breathability (MVTR) of at least 70% of its components including the inner layer 102, the metallized membrane 104, and the outer layer 106.

In some embodiments, the configuration of the breathable composite fabric 100 or 200 exposes the metallized membrane 104 (reflective layer) so that it does not block out the fabric's reflectivity on the outer layer side.

In some embodiments, when the point contacts 112, 114 are embodied with adhesive, the adhesive adds a weight fewer than 30 or 60 g/m².

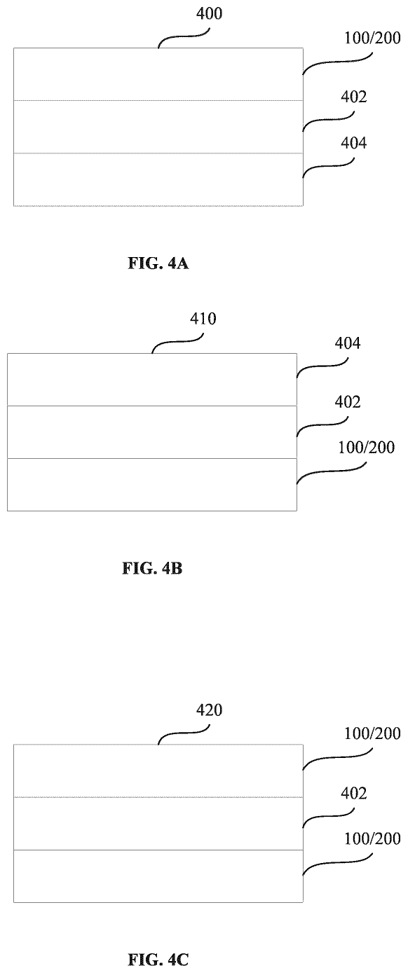

In some embodiments, the breathable composite fabric 100/200 may be used to make apparels, footwears, tents, sleeping bags, etc. In some embodiments, the breathable composite fabric 100/200 may be used with other materials to make apparels, footwears, tents, sleeping bags, etc. Example configurations are illustrated in FIGS. 4A-4C. FIG. 4A is a schematic diagram depicting a laminate 400 according to one example embodiment. The laminate 400 includes an outer layer made of the breathable composite fabric 100/200, an intermediate fibrous layer 402, and a single-layered fibric 404. In some embodiments, the intermediate fibrous layer 402 may include a fibrous insulation material, such as synthetic insulation, down, etc.

FIG. 4B is a schematic diagram depicting a laminate 410 according to one example embodiment. The laminate 410 includes an outer layer made of a single-layered fibric 404, an intermediate fibrous layer 402, and an inner layer made of the breathable composite fabric 100/200.

FIG. 4C is a schematic diagram depicting a laminate 420 according to one example embodiment. The laminate 420 includes an outer layer made of breathable composite fabric 100/200, an intermediate fibrous layer 402, and an inner layer made of the breathable composite fabric 100/200. It is to be understood that laminates 400, 410 and 420 are for illustration purpose only. Other structures using the breathable composite fabric 100/200 are contemplated.

This disclosure also provides an infrared-reflective breathable composite fabric that offers enhanced thermal insulation through infrared reflection. A three-layer composite where the middle layer is a breathable metallized layer mainly responsible for infrared reflection; while the inner and outer layers both provide strength and support so that the metallized layer can resist mechanical actions such as repeated rubbing and laundering. Further, the outer layer is chosen so that it not only protects the metallized layer from oxidation, hence avoiding the reduction in reflectivity, but also not to block off the fabric's outward-facing emissivity. An emissivity of at most 0.8 is demonstrated in providing effective warming performance (measured by thermal resistance) through IR reflection. The inner layer is also selected for giving a nice next-to-skin hand feel.

In one aspect, a breathable composite fabric disclosed herein has high breathability, which makes it more comfortable to be worn than garment made from non-porous reflective foil.

In another aspect, a breathable composite fabric disclosed herein includes a more effective reflection layer using a metallized membrane. The metallized membrane includes a base layer made of polyethylene, which has a lower melting point than many conventional fabric material so that it can achieve flatter surface through calendaring at a lower temperature, e.g., less than 200° C. or about 135° C.

In yet another aspect, a breathable composite fabric disclosed herein includes a base layer of polyethylene having a thin thickness of about 200 micrometers or less, making it fairly transparent (about 40-60%) to infra-red radiation from human body (wavelength about 7-14 micrometers). The breathable composite fabric thus maximizes thermal radiation to be reflected back to the body because minimal heat is consumed to warm up the layers due to absorption.

In another aspect, a breathable composite fabric disclosed herein provide better structural integrity and anti-oxidation ability than that of other meltspun non-woven materials, making the breathable composite fabric less susceptible to disintegration after washing.

In another aspect, a breathable composite fabric disclosed herein includes point contacts for adhering an inner layer and an outer layer to a metallized membrane, resulting in high breathability that is desirable for applications in apparels, footwears, tents, and sleeping bags, or other applications that need fabric materials.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

It should be understood that the various features, aspects (e.g., embodiments) and functionality described in one or more of the individual aspects are not limited in their applicability to the particular aspect with which they are described. Instead, they can be applied, alone or in various combinations, to one or more other aspects, whether or not such aspects are described and whether or not such features are presented as being a part of a described aspect. Thus, the breadth and scope of the present application should not be limited by any of the above-described exemplary aspects.

The presence of broadening words and phrases such as “one or more,” “at least,” “but not limited to” or other like phrases in some instances shall not be read to mean that the narrower case is intended or required in instances where such broadening phrases may be absent.

Reference to A “and” B may be construed to also encompass the scenario of A “or” B. Reference to A “or” B may be construed to also encompass the scenario of A “and” B. Any reference to “near,” a “threshold” or “sufficiency” may be construed to encompass any applicable value or degree, such as any applicable value or degree sufficient to satisfy a given outcome. In some examples, a threshold level, similarity or degree thereof may be construed to include any values such as 99 percent, 98 percent, 95 percent, 90 percent, 80 percent, 75 percent, or any other value therebetween, or any ranges therebetween. Additionally or alternatively, a threshold similarity, degree, or level may be construed as qualitatively satisfying some condition. For example, a threshold level of thermal conductivity or moisture vapor transmission rate may be construed as qualitatively satisfying a condition of skin comfort or skin safety (e.g., preventing or not causing sickness or a safety-related event in a human subject or a vast majority of human subjects, such as 99 percent, 99.9 percent, or any other appropriate percentage of human subjects).

What is claimed is:

1. A fabric comprising:
an inner layer;
a metallized membrane disposed on the inner layer, the metallized membrane including a base layer containing a polyethylene and a metal layer deposited on a first surface of the base layer, wherein the inner layer is coupled to the metallized membrane via first point contacts, wherein a first density of the first point contacts is variable across different portions of the inner layer, wherein, an area covered by the first point contacts is below 20 percent of a surface of the outer layer; and
an outer layer disposed on the metallized membrane, wherein the outer layer is coupled to the metallized membrane via second point contacts, wherein a second density of the second point contacts is variable across different portions of the outer layer.

2. The fabric according to claim 1, wherein the first density of the first point contacts or the second density of the second point contacts is different along different directions, the different directions comprising a horizontal direction and a vertical direction.

3. The fabric according to claim 2, wherein the first density of the first point contacts is different from the second density of the second point contacts.

4. The fabric according to claim 3, wherein the first density of the first point contacts or the second density of the second point contacts is different along different orthogonal directions.

5. The fabric according to claim 3, wherein each of the inner layer, the base layer, the metal layer, and the outer layer has a moisture vapor transmission rate of at least 500 g/m²/24 hr, wherein the moisture vapor transmission rate is indicative of a degree of breathability.

6. The fabric according to claim 4, wherein the fabric has a thermal conductivity at most 0.6 W/m-K.

7. The fabric according to claim 5, wherein the inner layer includes one of a woven fabric, a knit fabric, or a non-woven fabric.

8. The fabric according to claim 6, wherein the inner layer includes a synthetic material or a natural material.

9. The fabric according to claim 7, wherein the synthetic material is selected from one or more of polyester, nylon, elastane, polyurethane, polyolefin, polylactic acid, or polytetrafluoroethylene (PTFE).

10. The fabric according to claim 8, wherein the fabric has a moisture vapor transmission rate at least 70% of each of the inner layer, the metallized membrane, and the outer layer.

11. The fabric according to claim 9, wherein the first and second point contacts include an adhesive.

12. The fabric according to claim 10, wherein the first point contacts include melted base layer.

13. The fabric according to claim 11, wherein the first point contacts include melted inner layer.

14. The fabric according to claim 12, wherein the second point contacts include melted base layer.

15. The fabric according to claim 13, wherein the second point contacts include melted outer layer.

16. The fabric according to claim 14, wherein the first point contacts or the second point contacts are formed by sewing or quilting.

17. The fabric according to claim 15, wherein the metal layer comprises one or more of aluminum, titanium, silver, gold, copper, zinc, magnesium, or germanium.

18. The fabric according to claim 16, wherein the metal layer has a thickness of 10 nanometers to 200 nanometers and, wherein the metal layer has a reflectivity in a range between 0.76 and 0.97 at a wavelength of 9.5 micrometers.

19. The fabric according to claim 18, wherein the metallized membrane has a moisture vapor transmission rate of at least 800 g/m²/24 hr.

20. The fabric according to claim 19, wherein a combined emissivity of the metallized membrane and the outer layer is at most 0.85 at a wavelength of 9.5 micrometers, wherein the combined emissivity indicates an emissivity of a combination of the metallized membrane and the outer layer.
